(19) United States
(12) Patent Application Publication
(10) Pub. No.: US 2003/0006848 A1
(43) Pub. Date: Jan. 9, 2003

(54) Frequency synthesizer having a phase-locked loop with circuit for reducing power-on switching transients

(76) Inventor: Jose Luis Cordoba, San Jose, CA (US)

Correspondence Address: Philips Electronics North America Corporaion, Corporate Patent Counsel, 580 White Plains Road, Tarrytown, NY, 10591, US

(21) Appl. No.: 10/030,594

(22) PCT Filed: May 10, 2001
(86) PCT No.: PCT/EP01/05477

(30) Foreign Application Priority Data
May 10, 2000 (EP) 00401281.1

(51) Int. Cl. H03L 7/00

(52) U.S. Cl. 331/17

(57) ABSTRACT

A phase-locked loop synthesizer (8) has a charge pump (9) and a loop filter (22) with a frequency preset capacitor (27). The synthesizer (8) has a transistor (34) of which one main electrode (36) is connected to the frequency preset capacitor. Another main electrode (35) of the transistor (34) is connected to a power-up terminal (32) that is also connected to the charge pump (21). Upon powering up, the transistor (34) causes the frequency preset capacitor (27) to quickly charge before a first pulse of the charge pump (21).

### BACKGROUND OF THE INVENTION

1. Field of the Invention

The present invention relates to a frequency synthesizer for use in a transceiver, receiver, or transmitter, or the like, more particularly to a frequency synthesizer with frequency preset upon powering up.

2. Description of the Related Art

In the U.S. Pat. No. 5,389,899, a frequency synthesizer is disclosed including a phase-locked loop circuit. The phase-locked loop circuit has a phase comparator, a charge pump, a loop filter, and a voltage controlled oscillator. An output of the voltage controlled oscillator, providing an output signal of the frequency synthesizer, is coupled, through a frequency divider, to an input of the phase comparator. A reference oscillator is coupled to another input of the phase comparator. The phase-locked loop causes the frequency synthesizer to pull-in and to lock-in to a particular frequency. Such a phase-locked loop synthesizer is well-known in the art. In addition thereto, the loop filter has a frequency preset capacitor, and the phase-locked loop synthesizer has a preset circuit for quickly charging or discharging the frequency preset capacitor for switching the output of the voltage controlled oscillator. The preset circuit comprises a ROM-table of preset values, a digital-to-analog converter coupled to the ROM-table, a CPU, and a controlled switch or switches that couple an output of the digital-to-analog converter to the frequency preset capacitor. The operation of the preset circuit is as follows. In a power-down or power saving mode, with the frequency synthesizer and thereby charge pump switched off, the CPU causes addressing of the ROM-table such that a preset value is read out from the ROM-table that corresponds to a new frequency to be set in the frequency synthesizer. The read-out preset value is converted to an analog value by the digital-to-analog converter and is fed to the switch that is turned on at an appropriate timing during the period of the power saving mode. With the switch turned on, the read-out preset value is converted to an analog value that is applied to the capacitor of the loop filter. As a result of this, charging or discharging of the capacitor of the loop filter is performed so that the voltage across the capacitor is made to correspond to the read-out preset value. When the power saving signal is switched off, canceling the power saving mode, the switch is turned off, thereby disconnecting the capacitor from the preset circuit, and initiating normal operation of the synthesizer so as to achieve frequency lock-in and phase-lock-in with the set target frequency. So, presetting occurs in the power-saving mode, using an elaborate and complicated circuit formed by an addressed ROM and an digital-to-analog converter, and frequency lock-in and phase-lock-in occurs thereafter upon canceling the power-saving mode and powering up the frequency synthesizer and thereby the charge pump.

### SUMMARY OF THE INVENTION

It is an object of the invention to provide a phase-locked loop frequency synthesizer, that has a frequency preset capacitor, with a simple frequency preset circuit.

It is another object of the invention to provide that such a frequency preset circuit operates in cooperation with a charge pump comprised in the frequency synthesizer, upon simultaneously powering up the charge pump and the frequency preset circuit.

It is another object of the invention to provide such a preset circuit that automatically becomes inoperative to charge the capacitor in the loop filter, a predetermined time after the simultaneous powering up of the charge pump and the preset circuit.

It is still another object of the invention to provide an adjustable charging time.

In accordance with the invention, a frequency synthesizer is provided comprising:

a phase-locked loop comprising a cascade arrangement of a phase comparator, a charge pump, a loop filter, and a voltage controlled oscillator, an input of said phase comparator being coupled to an output of said voltage controlled oscillator, said loop filter comprising a first capacitor for, upon powering up of said frequency synthesizer, storing a frequency preset voltage, and said charge pump being coupled to a power-up terminal; and

a transistor of which a first main electrode is coupled to said power-up terminal, a second main electrode is coupled to said first capacitor, and a control electrode controls said storing of said frequency preset voltage when said power-up terminal carries a power-up signal.

The invention is based upon the insight that, through cooperation of the phase-locked loop with the preset circuit, the output frequency of the synthesizer quickly stabilizes, whereby charging of the loop capacitor, and pulling-in and locking-in of the phase-locked loop are all performed in non-power saving mode.

In a phase-locked loop synthesizer with a charge pump, but without a frequency preset capacitor and a preset circuit, due to the fact that overshoot in a voltage control signal of the voltage controlled oscillator is proportional to a frequency step to be made, either the charge pump should operate at a higher voltage than the frequency synthesizer of the invention, or the voltage controlled oscillator should operate at a higher control voltage control than the frequency synthesizer of the invention. Operation of the charge pump at a higher frequency gives rise to a higher power consumption, whereas operation of the voltage controlled oscillator at a higher control voltage gain gives rise to a degradation of phase noise performance.

In a first embodiment, the preset circuit comprises an RC-circuit coupled to the control electrode. Herewith, it is achieved that the transistor is shut-off automatically a predetermined time after powering up. The RC-circuit is preferably dimensioned such that said frequency preset voltage settles substantially in the mid of a range of voltages representing a band of frequencies generatable by said frequency synthesizer. By simultaneous powering up of the charge pump, and the automatically shut-off transistor through the RC-circuit, charging of the frequency preset capacitor is very fast, typically before the first pulse of the charge pump, after having been powered up.

In a second embodiment, the preset circuit is controlled by a pulse that is put onto the control electrode upon powering up of the charge pump. Preferably, the pulse width of the pulse is adjustable. Herewith, the transistor is quickly switched on and off, and the frequency preset capacitor is quickly charge with the charge pump already powered on. The pulse is preferable generated at an output gate of a microprocessor that can easily vary the pulse width when suitably programmed. By adjusting the pulse width, the capacitor of the loop filter can be preset to a value that cause the frequency synthesizer to quickly settle to a desired output frequency within a band of frequencies, typically even before the charge pump starts to work after having been powered on.

### BRIEF DESCRIPTION OF THE DRAWING

FIG. 1 is a block diagram of a transceiver according to the invention.

FIG. 2 shows a frequency synthesizer according to the invention.

FIG. 3 shows a first embodiment of a frequency preset control circuit according to the invention.

FIG. 4 shows a second embodiment of a frequency preset control circuit according to the invention.

FIG. 5 shows a timing diagram illustrating powering up of a frequency synthesizer according to the invention.

FIG. 6 shows charging of a preset capacitor in a frequency synthesizer according to the invention.

Throughout the figures the same reference numerals are used for the same features.

### DESCRIPTION OF THE DETAILED EMBODIMENTS

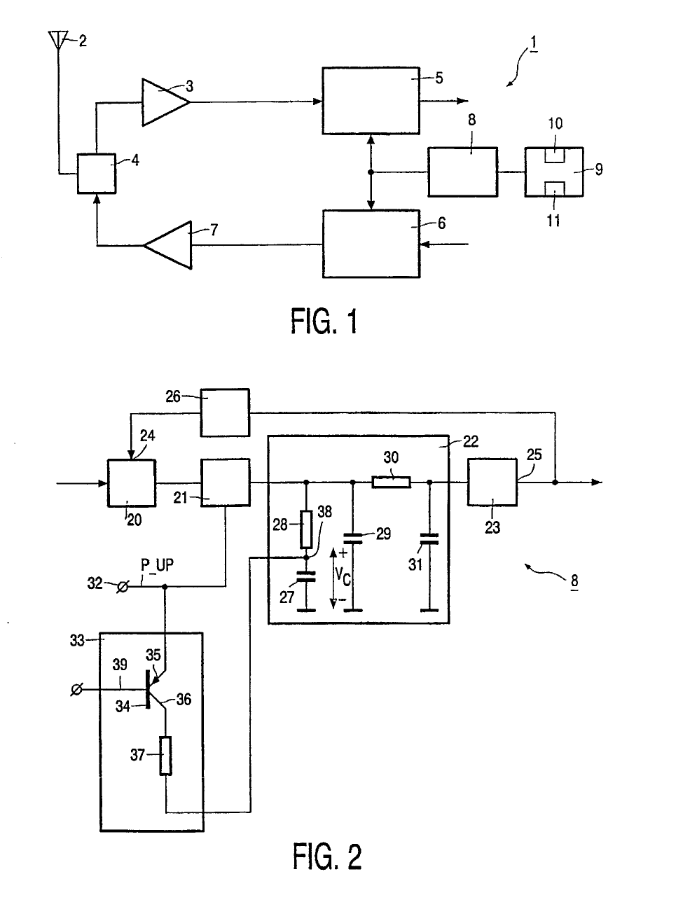

FIG. 1 is a block diagram of a transceiver 1 according to the invention. The transceiver 1 comprises a antenna 2 that is coupled to a low noise amplifier 3, in a receive branch, via a receive/transmit switch 4. The low noise amplifier 3 is coupled to a frequency down-converter 5. The transceiver 1 further comprises, in a transmit branch, a frequency up-converter 6 that is coupled to the receive/transmit switch 4 via a power amplifier 7. The transceiver 1 further comprises a frequency synthesizer 8 according to the invention, and a microcontroller 9 with RAM 10 and ROM 11. The ROM 11 is a programmed ROM for controlling the transceiver 1. The RAM 10, part of which can be non-volatile, stores data to be used by the stored program ROM 11. Shown is a single synthesizer transceiver operating at the same receive and transmit band. For operation at a different receive and transmit band the transceiver has two frequency synthesizers, and, for full duplex operation, a duplexer instead of a receive/transmit switch. The shown device can be a receiver only. In that case, the receive/transmit switch, and the transmit branch are lacking. The shown device can be a transmitter only. In that case, the receive/transmit switch, and the receive branch are lacking.

FIG. 2 shows the frequency synthesizer 8 according to the invention. The frequency synthesizer 8 comprises a cascade arrangement of a phase comparator 20, a charge pump 21, a loop filter 22, and a voltage controlled oscillator 23. As is well-known in the art, the charge pump 21 provides current pulses of one polarity that cause increasing the control voltage of the voltage controlled oscillator 23, and current pulses of an opposite polarity that cause decreasing the control voltage of the voltage controlled oscillator 23, such pulses being at equidistant intervals of, for example, 5 μsec. The shown synthesizer is a phase-locked loop synthesizer. An input 24 of the phase comparator 20 is coupled to an output 25 of the voltage controlled oscillator 23, via a frequency divider 26. The loop filter 22 comprises a capacitor 27 for, upon powering up of the frequency synthesizer 8, storing of a frequency preset voltage V_{C}. The loop filter 8 further comprises a resistor 28 in series with the capacitor 27, and a capacitor 29 in parallel to the series arrangement of the resistor 28 and the capacitor 27. The loop filter 8 further comprises a resistor 30 between the charge pump and the voltage controlled oscillator 23, to one end of which the resistor 28 and the capacitor 29 are connected, and to another end of which a capacitor 31 is connected. The charge pump 21 is coupled to a power-up terminal 32 for powering up of the frequency synthesizer 8. The frequency synthesizer 8 further comprises a frequency preset control circuit 33. The frequency preset control circuit comprises a transistor 34 of which a main electrode 35 is coupled to the power-up terminal, of which a main electrode 36 is coupled, via a resistor 37, to a junction 38 of the resistor 28 and the capacitor 27, and of which a control electrode 39 controls storing of the frequency preset voltage V_{C} when the power-up terminal 32 carries a power-up signal P_up.

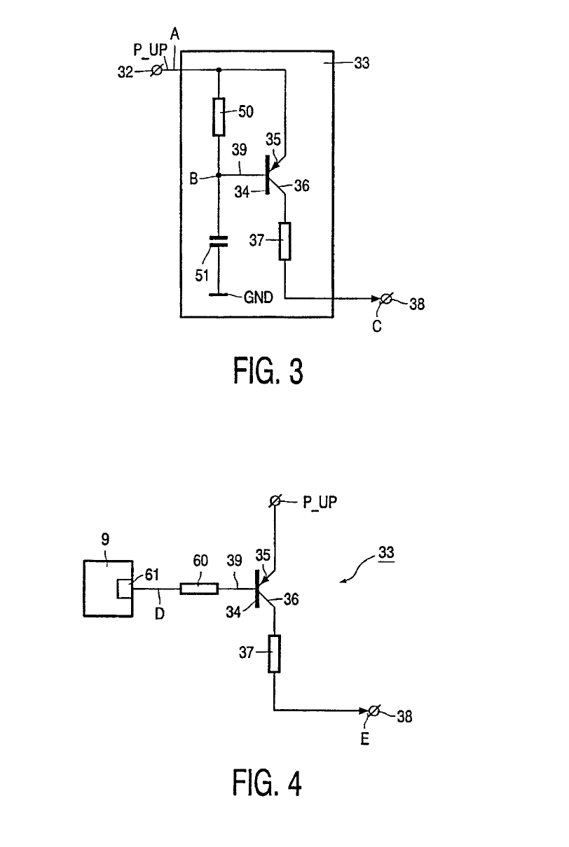

FIG. 3 shows a first embodiment of the frequency preset control circuit 33 according to the invention. In addition to the transistor 34 and the resistor 37, the frequency preset control circuit 33 comprises a resistor 50 coupled between the power-up terminal 32 and the control electrode 39, and a capacitor 51 coupled between the control electrode 39 and ground GND.

FIG. 4 shows a second embodiment of the frequency preset control circuit 33 according to the invention. In addition to the transistor 34 and the resistor 37, the frequency preset control circuit 33 comprises a resistor 60 coupled between the control electrode 39 and a gate 61 of the microcontroller 9.

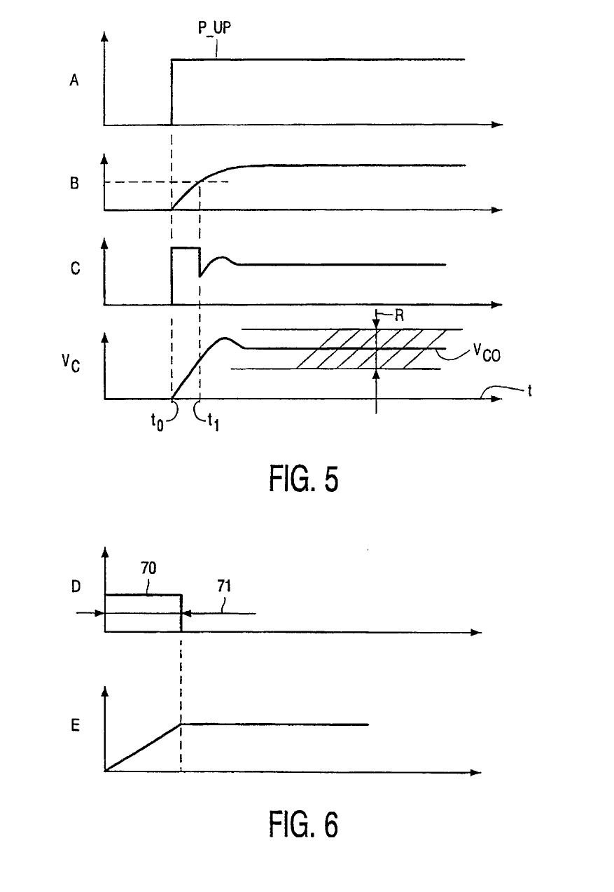

FIG. 5 shows a timing diagram illustrating powering up an operation of the frequency synthesizer 8 according to the invention, in the first embodiment. Shown are a voltage A at the power-up terminal 32, a voltage B at the control electrode 39, a voltage C at the junction 38, and the voltage V_{C} across the capacitor 27. Upon applying the power-up signal P_up at t=t_{O,} the RC-circuit formed by the resistor 50 and the capacitor 51 keeps the transistor 34 into saturation until the capacitor 51, at t=t₁, is charged through the resistor 50 to a voltage of approximately the voltage of the power-up signal P_up minus 0.6 V. After t=t₁ , the transistor 34 acts as an open circuit and no longer affects the loop response of the phase-locked loop synthesizer. As shown, the preset circuit causes the capacitor 27 to quickly charge to a voltage V_{CO}, preferably in the mid of a range R of voltages representing a band of frequencies that are generated by the synthesizer 8. The charge pump 21 causes the frequency synthesizer 8 to settle to a desired frequency, starting from the preset frequency. Because of a quick preset close to a desired final voltage, an thereby frequency, frequency settling exhibits a reduced overshoot. In addition to the capacitor 27 being charged, through the resistor 28 the capacitor 29 is also charged. Preferably, the capacitor 27 has a higher capacity than the capacitor 29. By coupling the transistor 34 to the higher capacity capacitor 27, a leaking current of the transistor 34 has less influence. Preferably, the RC-circuit is dimensioned such that the preset voltage at the capacitor 27 is obtained before the first pulse of the charge pump 21 after having been powered up.

FIG. 6 shows charging of the preset capacitor 27 in the frequency synthesizer 8 according to the invention, in the second embodiment. Shown are a voltage D outputted by the gate 61, and a voltage D at the junction 38. The voltage D is a pulse 70 generated by the programmed microcontroller 9 at the gate 61. A pulse width 71 of the pulse 70 is adjustable by the microcontroller 9, depending on the desired frequency to be locked to. The pulse width 71 is chosen such that the preset voltage corresponds to a final voltage at the control input of the voltage controlled oscillator 23 that represents the frequency to be locked to. The shown ramp voltage E charges the capacitor 27.

In view of the foregoing it will be evident to a person skilled in the art that various modifications may be made within the spirit and the scope of the invention as hereinafter defined by the appended claims and that the invention is thus not limited to the examples provided. The word “comprising” does not exclude the presence of other elements or steps than those listed in a claim.

1. A frequency synthesizer (8) comprising:
a phase-locked loop comprising a cascade arrangement of a phase comparator (20), a charge pump (21), a loop filter (22), and a voltage controlled oscillator (23), an input (24) of said phase comparator (20) being coupled to an output (25) of said voltage controlled oscillator (23), said loop filter (22) comprising a first capacitor (27) for, upon powering up of said frequency synthesizer (8), storing a frequency preset voltage (V_{C}), and said charge pump (21) being coupled to a power-up terminal (32); and
a transistor (34) of which a first main electrode (35) is coupled to said power-up terminal (32), a second main electrode (36) is coupled to said first capacitor (27), and a control electrode (39) controls said storing of said frequency preset voltage (VC) when said power-up terminal (32) carries a power-up signal (P_UP).

2. A frequency synthesizer (8) as claimed in claim 1, further comprising a first resistor (50) and a second capacitor (51), said first resistor (50) being coupled between said control electrode (39) and said power-up terminal (32), and said second capacitor (51) being coupled between said control electrode (39) and a reference terminal (GND), upon powering up said frequency preset voltage (V_{C}) settling within a range ((R) of voltages representing a band of frequencies generatable by said frequency synthesizer (8).

3. A frequency synthesizer (8) as claimed in claim 2, further comprising a second resistor (37), said second resistor (37) being coupled between said first capacitor (27) and said second main electrode (36).

4. A frequency synthesizer (8) as claimed in claim 1, wherein said loop filter (22) further comprises a third resistor (28) coupled in series with said first capacitor (27) and coupled to an output of said charge pump (21), and a third capacitor (31) coupled parallel to said series coupled third resistor (28) and first capacitor (27).

5. A frequency synthesizer (8) as claimed in claim 1, wherein upon powering up said control electrode (39) carries a pulse signal (70) controlling said storing of said frequency preset voltage (V_{C}), a pulse width (71) of said pulse signal (70) determining said frequency preset voltage (V_{C}) to settle within a range (R) of voltages representing a band of frequencies generatable by said frequency synthesizer.

6. A frequency synthesizer (8) as claimed in claim 5, wherein said pulse width (71) is adjustable.

7. A frequency synthesizer (8) as claimed in claim 5, wherein said pulse signal (70) is generated by a microprocessor (9).

8. A frequency synthesizer (8) as claimed in claim 5, further comprising a resistor (37), said resistor (37) being coupled between said first capacitor (27) and said second main electrode (36).

9. A receiver having a frequency synthesizer (8) for generating a receiver local oscillator signal, said frequency synthesizer (8) comprising:
a phase-locked loop comprising a cascade arrangement of a phase comparator (20), a charge pump (21), a loop filter (22), and a voltage controlled oscillator (23), an input (24) of said phase comparator (20) being coupled to an output (25) of said voltage controlled oscillator (23), said loop filter (22) comprising a first capacitor (27) for, upon powering up of said frequency synthesizer (8), storing a frequency preset voltage (V_{C}), and said charge pump (21) being coupled to a power-up terminal (32); and
a transistor (34) of which a first main electrode (35) is coupled to said power-up terminal (32), a second main electrode (36) is coupled to said first capacitor (27), and a control electrode (39) controls said storing of said frequency preset voltage (V_{C}) when said power-up terminal carries a power-up signal (P_UP).

10. A transmitter having a frequency synthesizer (8) for generating a transmitter local oscillator signal, said frequency synthesizer (8) comprising:
a phase-locked loop comprising a cascade arrangement of a phase comparator (20), a charge pump (21), a loop filter (22), and a voltage controlled oscillator (23), an input (24) of said phase comparator (20) being coupled to an output (25) of said voltage controlled oscillator (23), said loop filter (22) comprising a first capacitor (27) for, upon powering up of said frequency synthesizer (8), storing a frequency preset voltage (V_{C}), and said charge pump (21) being coupled to a power-up terminal (32); and
a transistor (34) of which a first main electrode (35) is coupled to said power-up terminal (32), a second main electrode (36) is coupled to said first capacitor (27), and a control electrode (39) controls said storing of said frequency preset voltage (V_{C}) when said power-up terminal (32) carries a power-up signal (P_UP).

11. A transceiver having a frequency synthesizer (8) for generating a receiver and transmitter local oscillator signal, said frequency synthesizer (8) comprising:
a phase-locked loop comprising a cascade arrangement of a phase comparator (20), a charge pump (21), a loop filter (22), and a voltage controlled oscillator (23), an input (24) of said phase comparator (20) being coupled to an output (25) of said voltage controlled oscillator (23), said loop filter (22) comprising a first capacitor (27) for, upon powering up of said frequency synthesizer (8), storing a frequency preset voltage (V_{C}), and said charge pump (21) being coupled to a power-up terminal (32); and
a transistor (34) of which a first main electrode (35) is coupled to said power-up terminal (32), a second main electrode (36) is coupled to said first capacitor (27), and a control electrode (39) controls said storing of said frequency preset voltage (V_{C}) when said power-up terminal (32) carries a power-up signal (P_UP).
